(19) United States
(12) Patent Application Publication
(10) Pub. No.: US 2025/0070047 A1
(43) Pub. Date: Feb. 27, 2025

(54) SEMICONDUCTOR DEVICE AND METHOD OF MANUFACTURING SEMICONDUCTOR DEVICE

(71) Applicant: SK hynix Inc., Gyeonggi-do (KR)

(72) Inventor: Yun Cheol HAN, Gyeonggi-do (KR)

(21) Appl. No.: 18/536,751

(22) Filed: Dec. 12, 2023

(30) Foreign Application Priority Data
Aug. 24, 2023 (KR) 10-2023-0111529

(51) Int. Cl. H01L 23/00; H01L 23/58

(52) U.S. Cl. CPC H01L 23/562; H01L 23/585

(57) ABSTRACT

A semiconductor device may include a stack including a chip region and a guard region surrounding the chip region, contact structures positioned in the chip region, and a chip guard structure positioned in the guard region and including first protrusions protruding by a first width and second protrusions protruding by a second width greater than the first width.

### CROSS-REFERENCE TO RELATED APPLICATION

This application claims priority under 35 U.S.C. § 119 to Korean Patent Application No. 10-2023-0111529 filed on Aug. 24, 2023, which is incorporated herein by reference in its entirety.

### BACKGROUND

### 1. Technical Field

Embodiments of the present disclosure relate to an electronic device and a method of manufacturing the electronic device, and more particularly, to a semiconductor device and a method of manufacturing the semiconductor device.

### 2. Related Art

An integration degree of a semiconductor device is mainly determined by an area occupied by a unit memory cell. Recently, as improvements in the integration degree of a semiconductor device in which a memory cell is formed as a single layer on a substrate reaches a limit, a three-dimensional semiconductor device in which memory cells are stacked on a substrate is being proposed. In addition, various structures and manufacturing methods are being developed in order to improve operation reliability of the semiconductor device.

### SUMMARY

According to an embodiment of the present disclosure, a semiconductor device may include a stack including a chip region and a guard region surrounding the chip region, contact structures positioned in the chip region, and a chip guard structure positioned in the guard region and including first protrusions protruding by a first width and second protrusions protruding by a second width greater than the first width.

According to an embodiment of the present disclosure, a method of manufacturing a semiconductor device may include forming a stack including a chip region and a guard region surrounding the chip region, forming first openings extending through the chip region of the stack, forming second openings and third openings extending through the guard region of the stack and spaced apart from each other, forming a fourth opening by connecting the second openings and the third openings, forming contact structures in the first openings, and forming a chip guard structure in the fourth opening.

These and other features and advantages of the invention will become apparent from the detailed description of embodiments of the invention and the following figures.

### BRIEF DESCRIPTION OF THE DRAWINGS

FIG. 1 is a diagram illustrating a semiconductor device according to an embodiment of the present disclosure.

FIGS. 2A to 2C are diagrams illustrating a semiconductor device according to an embodiment of the present disclosure.

FIGS. 3A to 7C are diagrams illustrating a method of manufacturing a semiconductor device according to an embodiment of the present disclosure.

### DETAILED DESCRIPTION

Embodiments of the present disclosure provides a semiconductor device and a method of manufacturing the semiconductor device having a stable structure and improved characteristic.

According to the present technology, a semiconductor device having a stable structure and improved characteristic may be provided.

Hereinafter, embodiments according to the technical spirit of the present disclosure are described with reference to the accompanying drawings.

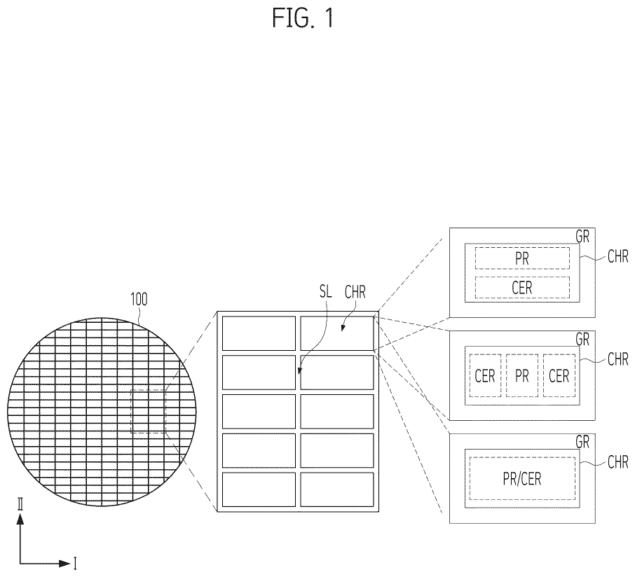

FIG. 1 is a diagram illustrating a semiconductor device according to an embodiment of the present disclosure.

Referring to FIG. 1, a substrate 100 may have a shape of a plate extended in a plane defined by a first direction I and a second direction II crossing the first direction I. The substrate 100 may include a plurality of chip regions CHR, a plurality of guard regions GR, and a scribe lane region SL. The chip region CHR may be a region in which semiconductor chips are formed. The semiconductor chips may be repeatedly formed on the substrate 100, and the plurality of chip regions CHR may be arranged in the first direction I and the second direction II. The scribe lane region SL may be positioned between the plurality of chip regions CHR. The scribe lane region SL may be a portion cut out in a dicing process for separating the semiconductor chips. The guard region GR may surround the chip region CHR of the semiconductor chips on the semiconductor chips. The guard region GR may include a chip guard structure, and prevent or reduce damage to the chip region CHR from a crack generated when dicing along the scribe lane region SL to separate the semiconductor chips.

The chip region CHR may include a cell region CER and a peripheral circuit region PR. For example, the chip region CHR may include a plurality of cell regions CER and a plurality of peripheral circuit regions PR. The plurality of cell regions CER and the plurality of peripheral circuit regions PR may be combined and arranged. For example, the peripheral circuit region PR may be positioned between the plurality of cell regions CER, or the cell region CER may be positioned between the plurality of peripheral circuit regions PR. Embodiments of the present disclosure are not limited thereto, and the cell region CER and the peripheral circuit region PR may be stacked. For example, the cell region CER may be positioned on the peripheral circuit region PR or may be positioned under the peripheral circuit region PR. For reference, although not shown in the present drawing, a pair of substrates 100 may be bonded. For example, the substrate 100 including the peripheral circuit region PR and the substrate 100 including the cell region CER may be bonded.

The cell region CER may be a region in which stacked memory cells are formed. For example, a cell array including memory strings may be positioned in the cell region CER. In the peripheral circuit region PR, a peripheral circuit may be positioned for driving the cell array formed in the cell region CER. The cell region CER may further include contact structures connected to the peripheral circuit of the peripheral circuit region PR.

According to the structure described above, the substrate 100 may include the chip region CHR and the guard region GR surrounding the chip region CHR. The guard region GR may minimize damage to the chip region CHR from a crack generated in a process of separating the semiconductor chips along the scribe lane region SL.

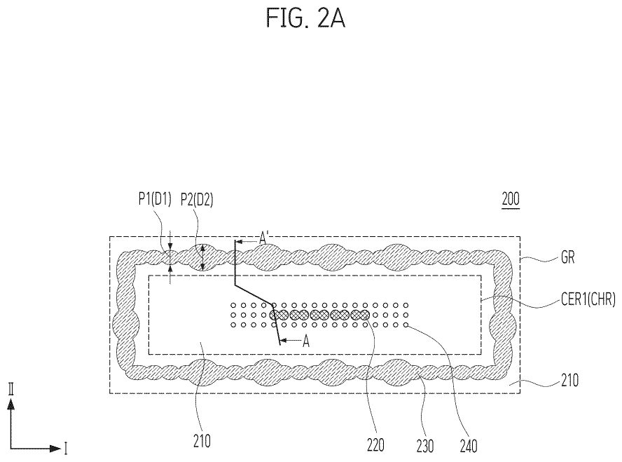

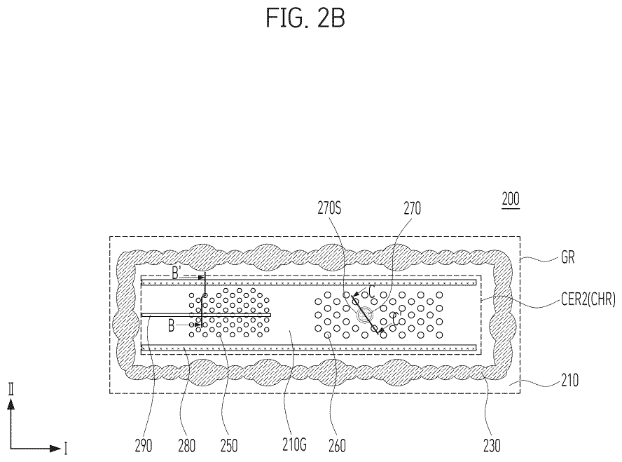

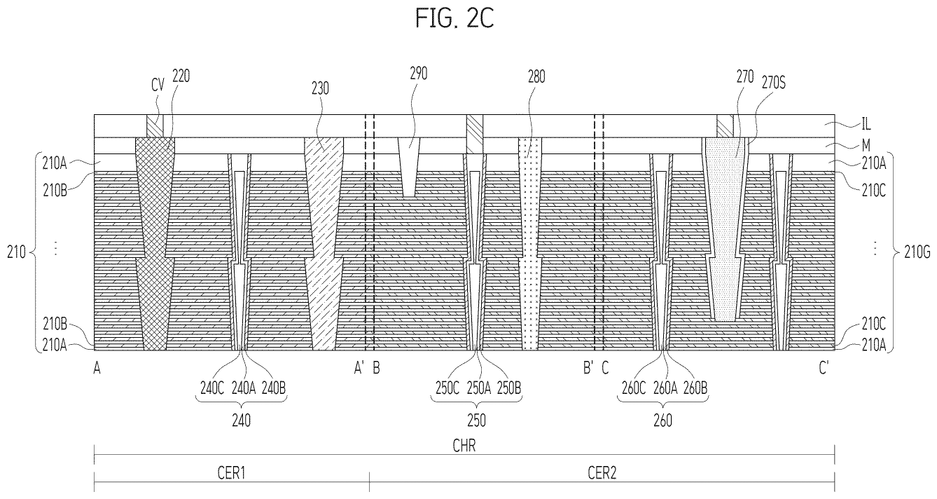

FIGS. 2A to 2C are diagrams illustrating a semiconductor device according to an embodiment of the present disclosure. FIGS. 2A and 2B may be plan views, and FIG. 2C may be a cross-sectional view A-A′ of FIG. 2A, a cross-sectional view B-B′, and a cross-sectional view C-C′ of FIG. 2B. Hereinafter, a content overlapping the content described above is omitted.

Referring to FIGS. 2A to 2C, the semiconductor device may include a semiconductor chip 200. The semiconductor chip 200 may include the chip region CHR and the guard region GR. A gate structure 210G may be positioned on the semiconductor chip 200. The gate structure 210G may be formed at a position corresponding to the chip region CHR or the guard region GR of the semiconductor chip 200. The gate structure 210G may include the chip region CHR and the guard region GR. A portion of the gate structure 210G may be a stack 210. Here, the stack 210 may remain without being replaced with the gate structure 210G in a manufacturing process.

The chip region CHR of the stack 210 may include a first cell region CER1 where contact structures 220 connected to the peripheral circuit are positioned, a second cell region CER2 where the cell array is positioned, and the peripheral circuit region (not shown) including the peripheral circuits. For reference, FIGS. 2A and 2B may show enlarged portions of a region for convenience of description of the first cell region CER1 and the second cell region CER. For example, FIG. 2A may be an enlarged view of the first cell region CER1, and FIG. 2B may be an enlarged view of the second cell region CER2 of the chip region CHR. Here, the first cell region CER1 and the second cell region CER2 may be spaced apart or connected to each other. Alternatively, the first cell region CER1 and the second cell region CER2 may be stacked. The peripheral circuit region may be spaced apart from the first cell region CER1 and the second cell region CER2 or may be stacked with the first cell region CER1 or the second cell region CER2. However, the present disclosure is not limited thereto, and the first cell region CER1, the second cell region CER2, and the peripheral circuit region may be combined and positioned in various methods.

At least one of the contact structures 220, first supports 240, channel structures 250, second supports 260, a first contact via 270, a insulating spacer 270S, a slit structure 280, an isolation insulating structure 290, and a second contact via CV may be positioned in the chip region CHR of the stack 210. For example, at least one of the contact structures 220 and the first supports 240 may be positioned in the first cell region CER1. At least one of the channel structures 250, the second supports 260, the first contact via 270, the insulating spacer 270S, the slit structure 280, and the isolation insulating structure 290 may be positioned in the second cell region CER2. The guard region GR of the stack 210 may include a chip guard structure 230.

The stack 210 may include alternately stacked insulating layers 210A and sacrificial layers 210B. The gate structure 210G may include alternately stacked insulating layers 210A and conductive layers 210C. Here, the insulating layers 210A may include an insulating material such as oxide, and the sacrificial layers 210B may include a sacrificial material such as nitride. The conductive layers 210C may include a conductive material such as tungsten, polysilicon, or molybdenum.

Referring to FIGS. 2A and 2C, the contact structures 220 may be positioned in the chip region CHR. For example, the contact structures 220 may be positioned in the first cell region CER1. The contact structures 220 may extend through the stack 210. For example, the contact structures 220 may extend into the stack 210 through a mask pattern M. Here, the mask pattern M may be positioned on the stack 210 and may remain without being removed during a manufacturing process. The mask pattern M may include polysilicon or the like.

A sidewall of the contact structures 220 may include a curved surface in a plane defined by the first direction I and the second direction II crossing the first direction I. For example, the contact structure 220 may have a dumbbell shape. This is because openings formed in correspondence with a position where the contact structures 220 are to be formed may be extended and adjacent openings may be connected in a process of forming the contact structures 220. The contact structures 220 may include at least one of titanium nitride, tungsten, molybdenum, and polysilicon.

The first supports 240 may be positioned in the chip region CHR. For example, the first supports 240 may be positioned in the first cell region CER1. The first supports 240 may be arranged around the contact structures 220 in the first direction I and the second direction II. The first supports 240 may be for preventing or reducing bending of the stack 210 during a manufacturing process. The first supports 240 may have a structure similar to that of the channel structures 250. For example, the first supports 240 may include a first dummy channel structure 240A, a first dummy memory layer 240B surrounding the first dummy channel structure 240A, and a first dummy insulating core 240C in the first dummy channel structure 240A.

The chip guard structure 230 may be positioned in the guard region GR. The chip guard structure 230 may extend through the stack 210. For example, the chip guard structure 230 may extend into the stack 210 through the mask pattern M. The chip guard structure 230 may be formed simultaneously with the contact structures 220. An upper surface of the chip guard structure 230 may be positioned at the same level as an upper surface of the contact structures 220. For example, the upper surface of the chip guard structure 230 may be positioned at substantially the same level as the upper surface of the contact structures 220. Here, the meaning of “substantially the same” may mean that they are the same, including an error range within a range that a person having ordinary skill in the technical field of the present disclosure may understand. Hereinafter, the present disclosure is described with reference to this. In addition, the chip guard structure 230 and the contact structures 220 may include substantially the same material. For example, the chip guard structure 230 may include at least one of titanium nitride, tungsten, molybdenum, and polysilicon. However, the present disclosure is not limited thereto, the chip guard structure 230 and the contact structures 220 may be formed at different times and may include different materials.

The chip guard structure 230 may have a ring shape in a plane, e.g., a rectangular ring shape as illustrated in the described embodiments of FIGS. 2A and 2B. The chip guard structure 230 may surround the chip region CHR and may prevent or reduce damage to the chip region CHR in a process of separating the semiconductor chips. The chip guard structure 230 may include a plurality of first and a plurality of second protrusions P1 and P2. The first and second protrusions may each have a concave shape. The chip guard structure 230 may have a ring shape cross-section, (for example a rectangular ring shape) with sides comprising consecutive concave first and second protrusions P1 and P2.

The second protrusions P2 may be disposed individually between a plurality of consecutive first protrusions P1 as illustrated in the described embodiment of FIGS. 2A and 2B.

For example, the first protrusions P1 may be successively arranged in a pattern of 2, or three, or more, adjacent to each other. The second protrusions P2 may be individually arranged between the first protrusions P1. For example, as shown in FIG. 2B, a single second protrusion may be disposed every other 3 first protrusions in some parts of the ring of the chip guard structure 230 or every other 5 protrusions in other parts of the ring of the chip guard structure 230. However, it is noted that the number of the first and second protrusions may vary by design.

The first protrusions P1 may have a first width D1, and the second protrusions P2 may have a second width D2 greater than the first width D1. For reference, the first protrusions P1 may be formed to have a uniform first widths D1 or a different first widths D1 during the manufacturing process. For example, the first widths D1 may be all uniform. The first widths D1 may be different at top, bottom and sides. As the chip guard structure 230 includes the second protrusions P2 having a relatively large second width D2, even though cracks occur in the process of separating the semiconductor chips, the cracks may be prevented or reduced from occurring into the chip region CHR, and thus the chip region CHR might not be damaged.

Referring to FIGS. 2B and 2C, the channel structures 250 may be positioned in the chip region CHR. For example, the channel structures 250 may be positioned in the second cell region CER2. The channel structures 250 may extend through the gate structure 210G. The channel structures 250 may be arranged in the first direction I and the second direction II. The channel structures 250 may be arranged in a staggered shape of which a center is misaligned. The channel structures 250 may be formed simultaneously with the first supports 240. Accordingly, the channel structures 250 and the first supports 240 may have similar structures. The channel structures 250 may include a channel layer 250A, a memory layer 250B surrounding the channel layer 250A, and an insulating core 250C in the channel layer 250A. An upper surface of the channel structures 250 may be positioned at substantially the same level as an upper surface of the first supports 240.

The second supports 260 may be positioned in the chip region CHR. For example, the second supports 260 may be positioned in the second cell region CER2. The second supports 260 may extend through the gate structure 210G. The second supports 260 may be arranged in the first direction I and the second direction II. The second supports 260 may be arranged in a staggered shape of which a center is misaligned. The second supports 260 may be formed simultaneously with the channel structures 250 or the first supports 240. Accordingly, the second supports 260 may include a second dummy channel layer 260A, a second dummy memory layer 260B surrounding the second dummy channel layer 260A, and a second dummy insulating core 260C in the second dummy channel layer 260A.

The first contact via 270 may be positioned in the chip region CHR. For example, the first contact via 270 may be positioned in the second cell region CER2. The first contact via 270 may extend through the gate structure 210G. For example, the first contact via 270 may extend into the gate structure 210G through the mask pattern M. The first contact via 270 may be connected to at least one of the conductive layers 210C. The first contact via 270 may be positioned between the second supports 260. The first contact via 270 may include a conductive material such as tungsten or molybdenum.

The insulating spacer 270S may cover the sidewalls of the contact via 270. The insulating spacer 270S may prevent the contact via 270 connecting to the remaining conductive layers 210C except for the conductive layer 210C connecting to the contact via. The insulating spacer 270S may include insulating material such as oxide.

For reference, although not shown in the present drawing, the semiconductor device may include a plurality of first contact vias 270. The plurality of first contact vias 270 may be connected to the conductive layers 210C of the gate structure 210G, respectively. Accordingly, heights of the plurality of first contact vias 270 may be different from each other.

The second contact vias CV may be positioned in the chip region CHR. The second contact vias CV may be connected to the channel structures CH, the first contact via 270, and the contact structures 220, respectively. For example, the second contact vias CV may extend through an interlayer insulating layer IL and may be connected to the channel structures CH, the first contact via 270, and the contact structures 220, respectively. The second contact vias CV may be electrically connected to structures in the first cell region CER1 and the second cell region CER2, and may be used for transferring a voltage or a current applied to the first cell region CER1 and the second cell region CER2 to each of the structures. Here, the interlayer insulating layer IL may be positioned on the mask pattern M and may include an insulating material such as oxide. The second contact vias CV may include a conductive material such as tungsten or molybdenum.

According to the structure as described above, the chip guard structure 230 may include the first and second protrusions P1 and P2. When the chip guard structure 230 includes the second protrusions P2 having a relatively larger second width D2, cracks may be prevented or reduced from occurring in the chip region CHR during the process of separating the semiconductor chips.

In addition, the contact structures 220 and the chip guard structure 230 may be simultaneously formed. Accordingly, an upper surface of the contact structures 220 and an upper surface of the chip guard structure 230 may be positioned on substantially the same level and may include substantially the same material. In addition, the channel structures 250, the first supports 240, and the second supports 260 may be simultaneously formed. Accordingly, the channel structures 250, the first supports 240, and the second supports 260 may have structures similar to each other. A process of forming the semiconductor device may be simplified by unifying a process of forming the contact structures 220 and the chip guard structure 230 and unifying a process of forming the channel structures 250, the first supports 240, and the second supports 260.

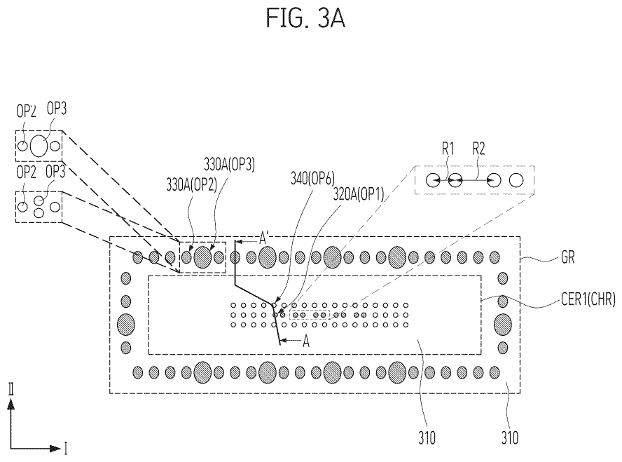

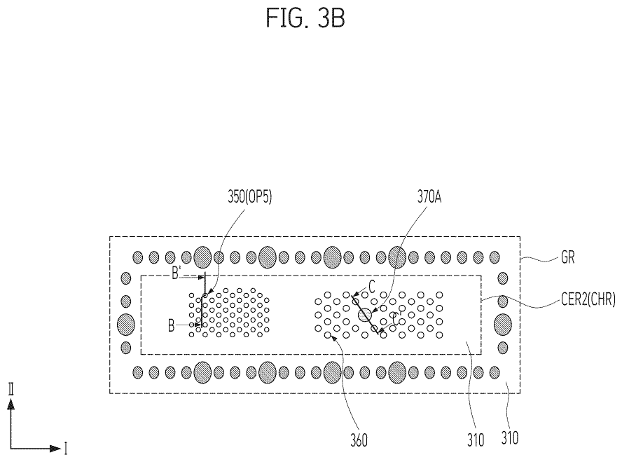

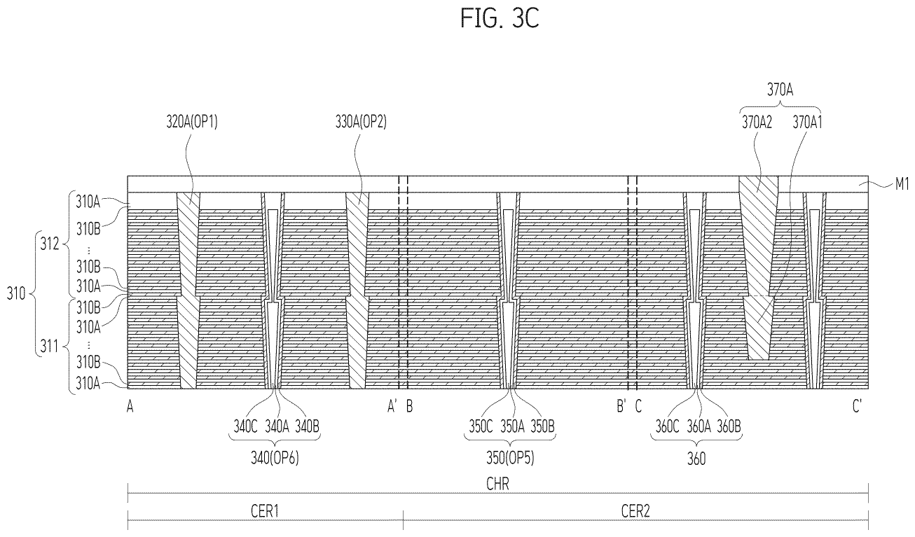

FIGS. 3A to 7C are diagrams illustrating a method of manufacturing a semiconductor device according to an embodiment of the present disclosure. FIGS. 3A, 3B, 4A, 4B, 5A, 6A, 7A, and 7B are plan views, and FIGS. 3C, 4C, 5B, 6B, and 7C are cross-sectional views of each A figure or B figure. Hereinafter, content overlapping with the content described above may be omitted.

Referring to FIGS. 3A to 3C, a first sub-stack 311 may be formed by alternately stacking first and second material layers 310A and 310B. The first sub-stack 311 may be formed. A first sacrificial contact via 370A1 may be formed in the first sub-stack 311. The first sacrificial contact via 370A1 may include a sacrificial material such as polysilicon or carbon. For reference, although one first sacrificial contact via 370A1 is shown in the present drawing, a plurality of first sacrificial contact vias 370A1 may be formed in the first sub-stack 311. Each of the first sacrificial contact vias 370A1 may be formed at different heights to be connected to the second material layers 310B of the first sub-stack 311.

Subsequently, a second sub-stack 312 may be formed by alternately stacking the first material layers 310A and the second material layers 310B on the first sub-stack 311. Accordingly, a stack 310 including the first sub-stack 311 and the second sub-stack 312 may be defined. Therefore, the stack 310 may include the alternately stacked first material layers 310A and second material layers 310B. The stack 310 may include the chip region CHR and the guard region GR surrounding the chip region CHR. The chip region CHR may include the second cell region CER2 and the first cell region CER1. For reference, the first sacrificial contact via 370A1 may be formed in the second cell region CER2.

First openings OP1 extending through the stack 310 may be formed. The first openings OP1 may extend through the chip region CHR of the stack 310. For example, the first openings OP1 may be formed in the first cell region CER1. The first openings OP1 may be spaced apart from each other. For example, the first openings OP1 may be spaced apart in a grip unit. The first openings OP1 belonging to the same group may be spaced apart by a first distance R1, and the first openings OP1 of different groups may be spaced apart by a second distance R2 greater than the first distance R1. Subsequently, sacrificial contact structures 320A may be formed in the first openings OP1. The sacrificial contact structure 320A may include a sacrificial material such as carbon or polysilicon.

Second openings OP2 and third openings OP3 extending through the stack 310 may be formed. The second openings OP2 and the third openings OP3 may extend through the guard region GR and may be spaced apart from each other. When forming the first openings OP1, the second openings OP2 and the third openings OP3 may be formed. The second openings OP2 and the third openings OP3 may have similar or different shapes, arrangements, or sizes. For example, the second openings OP2 and the third openings OP3 may have a hole shape arranged in the first direction I, and the third openings OP3 may have a width greater than that of the second openings OP2. As another example, the second openings OP2 may be arranged in the first direction I, and the third openings OP3 may be arranged in the second direction II crossing the first direction I. Alternatively, the second openings OP2 may have a hole shape, and the third openings OP3 may have an elliptical shape extended in the second direction II. Subsequently, sacrificial chip guard structures 330A may be formed in the second openings OP2 and the third openings OP3. When forming the sacrificial contact structures 320A, the sacrificial chip guard structures 330A may be formed. The sacrificial chip guard structures 330A may include a sacrificial material such as polysilicon or carbon.

Fifth openings OP5 extending through the chip region CHR of the stack 310 may be formed. For example, the fifth openings OP5 may be formed in the second cell region CER2. When forming the first openings OP1, the second openings OP2, and the third openings OP3, the fifth openings OP5 may be formed. Subsequently, channel structures 350 may be formed in the fifth openings OP5. The channel structure 350 may include a channel layer 350A, a memory layer 350B surrounding the channel layer 350A, and an insulating core 350C in the channel layer 350A.

Sixth openings OP6 extending through the chip region CHR of the stack 310 may be formed. For example, the sixth openings OP6 may be formed in the second cell region CER2. When forming at least one of the first openings OP1, the second openings OP2, the third openings OP3, and the fifth openings OP5, the sixth openings OP6 may be formed. Subsequently, first supports 340 may be formed in the sixth openings OP6. When forming the channel structures 350, the first supports 340 may be formed. The first supports 340 may have a structure similar to that of the channel structures 350. The first supports 340 may include a first dummy channel layer 350A, a first dummy memory layer 350B surrounding the first dummy channel layer 350A, and a first dummy insulating core 350C in the first dummy channel layer 350A.

Second supports 360 extending through the chip region CHR of the stack 310 may be formed. The second supports 360 may be simultaneously formed with at least one of the channel structures 350 and the first supports 340 and may have a similar structure. The second supports 360 may include a second dummy channel layer 360A, a second dummy memory layer 360B surrounding the second dummy channel layer 360A, and a second dummy insulating core 360C in the second dummy channel layer 360A.

Subsequently, a first mask pattern M1 may be formed on the stack 310. Here, the first mask pattern M1 may open a position corresponding to the first sacrificial contact via 370A1 and cover a remaining region. Subsequently, the stack 310 may be etched using the first mask pattern M1 as an etch barrier to expose the first sacrificial contact via 370A1, and a second sacrificial contact via 370A2 may be formed on the first sacrificial contact via 370A1. Accordingly, a sacrificial contact via 370A including the first sacrificial contact via 370A1 and the second sacrificial contact via 370A2 may be formed. Here, the second sacrificial contact via 370A2 may include substantially the same material as the first sacrificial contact via 370A1 and may include a sacrificial material such as polysilicon or carbon.

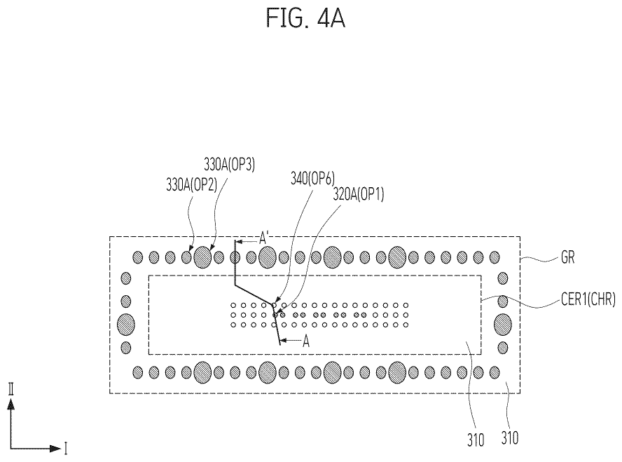

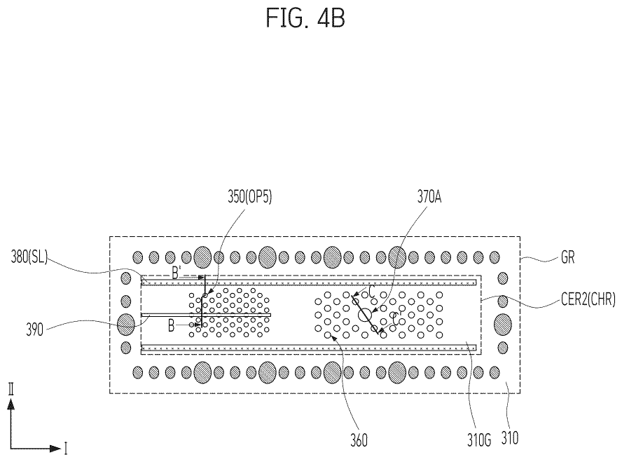

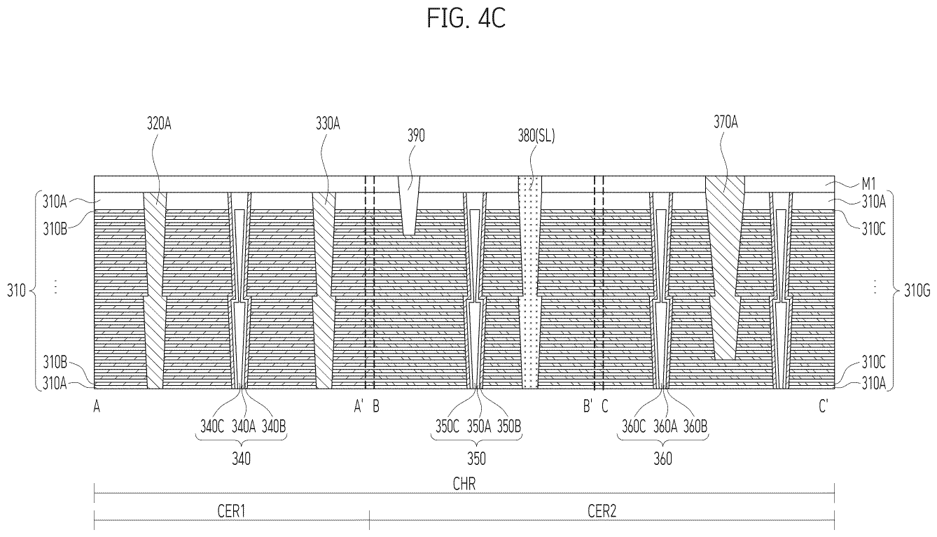

Referring to FIGS. 4A to 4C, a slit SL extending through the chip region CHR of the stack 310 may be formed. The slit SL may extend in the first direction I. Subsequently, the second material layers 310B may be replaced with third material layers 310C through the slit SL. Here, the second cell region CER2 may be replaced with the third material layers 310C, and the first cell region CER1 might not be replaced with the third material layers 310C and the sacrificial layers 310B may remain. The third material layers 310C may include a conductive material such as tungsten, polysilicon, or molybdenum. Accordingly, the gate structure 310G including the alternately stacked first material layers 310A and third material layers 310C may be formed. However, when the second material layers 310B include a conductive material, a process of replacing the second material layers 310B with the third material layers 310C may be omitted. In this case, the stack 310 may be used as the gate structure 310G. Subsequently, a slit structure 380 may be formed in the slit SL. Here, the slit structure 380 may include at least one of an insulating material such as oxide, a conductive material, and a semiconductor material.

An isolation insulating structure 390 may be formed through the chip region CHR of the stack 310. The isolation insulating structure 390 may extend in the first direction I and may be positioned between the channel structures 350. Here, the isolation insulating structure 390 may partially penetrate at least one of the channel structures 350 as shown in FIG. 4B. The isolation insulating structure 390 may have a height less than that of the slit structure 380. The isolation insulating structure 390 may have a height penetrating a source select line or a drain select line. The isolation insulating structure 390 may include an insulating material such as oxide.

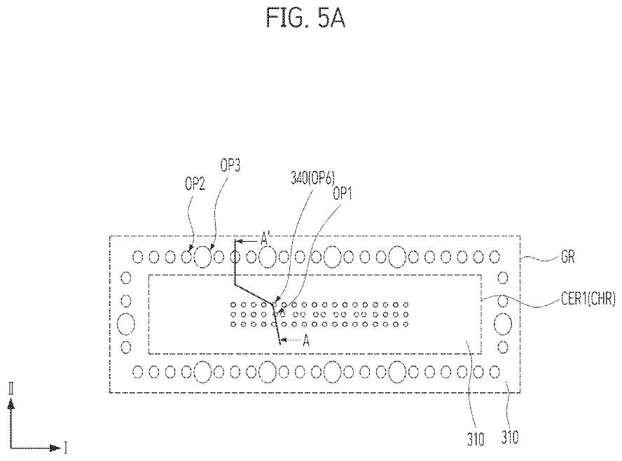

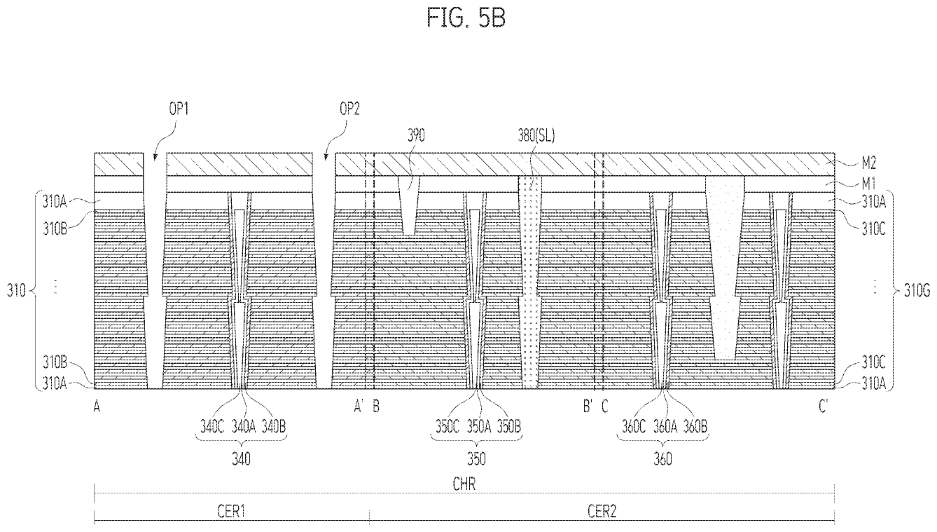

Referring to FIGS. 5A and 5B, a second mask pattern M2 may be formed on the first mask pattern M1. Here, the second mask pattern M2 may cover at least one of the channel structures 350 and the first supports 340, and expose the first openings OP1, the second openings OP2, and the third openings OP3. The second mask pattern M2 may expose the sacrificial contact structure 320A and the sacrificial chip guard structures 330A. Subsequently, the first mask pattern M1, the sacrificial contact structure 320A, and the sacrificial chip guard structures 330A may be etched using the second mask pattern M2 as an etch barrier, to reopen the first openings OP1, the second openings OP2, and the third openings OP3.

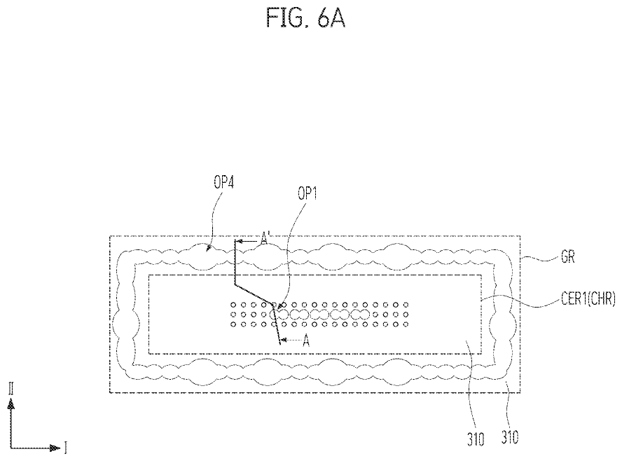

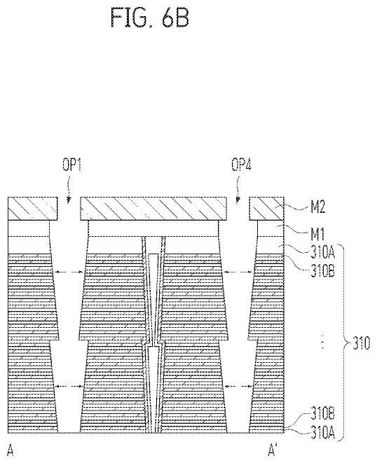

Referring to FIGS. 6A and 6B, the stack 310 may be selectively extended using the second mask pattern M2 as an etch barrier. First, a portion of the first material layers 310A exposed by the first openings OP1, the second openings OP2, and the third openings OP3 may be removed. Subsequently, a portion of the second material layers 310B may be removed. The first openings OP1, the second openings OP2, and the third openings OP3 may be extended by removing the first material layers 310A and the second material layers 310B. The second openings OP2 and the third openings OP3 may be connected to form a fourth opening OP4. When forming the fourth opening OP4, each of the first openings OP1 may be extended. Here, the first openings OP1 formed at adjacent positions may be connected. Referring back to FIG. 3A, the first openings OP1 spaced apart at a relatively small first distance R1 may be connected to each other. For example, the first openings OP1 belonging to the same group may be connected to each other, and the first openings OP1 of different groups may maintain spaced apart state.

The fourth opening OP4 may be formed in the guard region GR and may have a ring shape surrounding the chip region CHR. Here, the fourth opening OP4 may include protrusions having different widths. Referring back to FIG. 3A, the second openings OP2 and the third openings OP3 may have different shapes, arrangements, or sizes. For example, the third openings OP3 may have a width greater than that of the second openings OP2, and the third openings OP3 may be arranged in the second direction II. Accordingly, the fourth opening OP4 may include protrusions having a relatively large width.

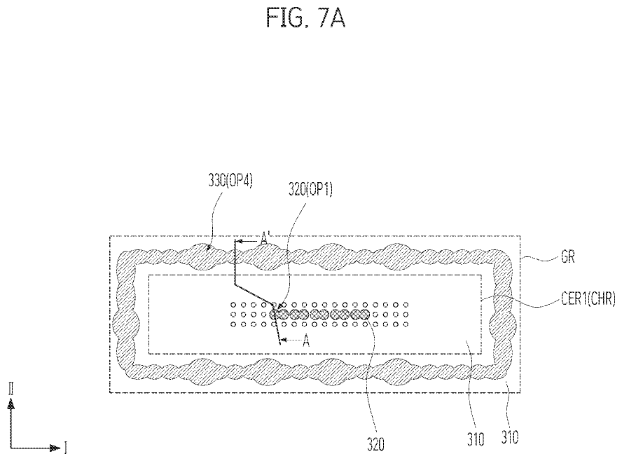

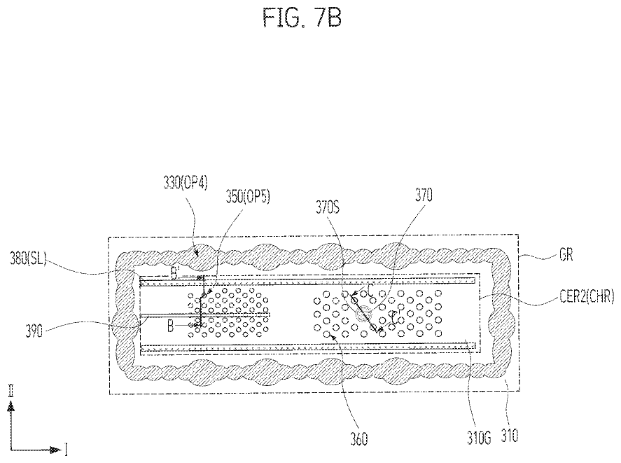

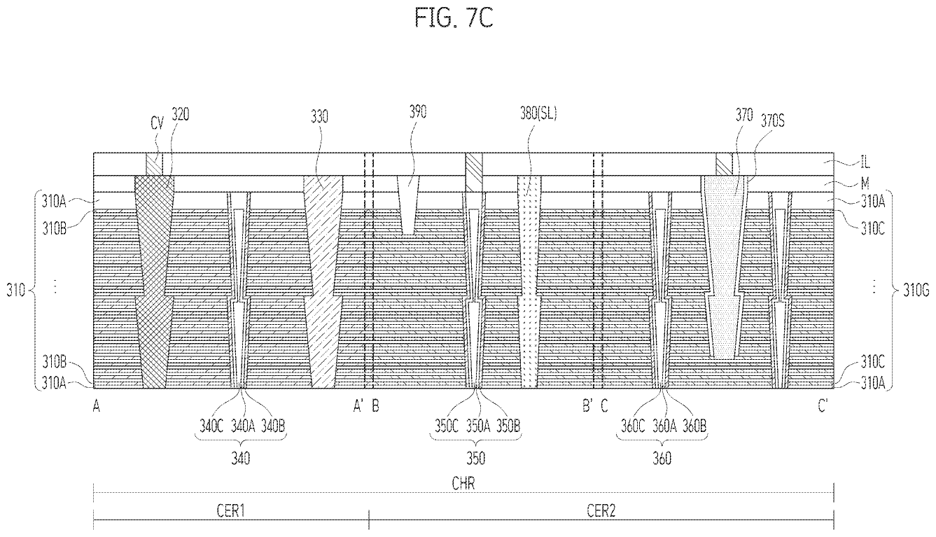

Referring to FIGS. 7A to 7C, a sacrificial material (not shown) may be formed in the first openings OP1 and the fourth openings OP4. Here, the sacrificial material may include a sacrificial material such as polysilicon or tungsten. Subsequently, the second mask pattern M2 may be removed. Subsequently, the sacrificial material formed in the sacrificial contact via 370A, the first openings OP1, and the fourth openings OP4 may be removed.

Subsequently, contact structures 320 may be formed in the first openings OP1. The contact structures 320 may be formed in the first cell region CER1 and may be connected to the peripheral circuits formed in the chip region CHR. Because the contact structures 320 are formed after extending and connecting the first openings OP1 to each other, a resistance of the contact structures 320 connected to the peripheral circuits may be reduced. The contact structures 320 may include titanium nitride, tungsten, molybdenum, or the like.

A chip guard structure 330 may be formed in the fourth opening OP4. The chip guard structure 330 may be formed in the guard region GR. When forming the chip guard structure 330, the contact structures 320 may be formed. Accordingly, an upper surface of the chip guard structure 330 may be positioned at substantially the same level as an upper surface of the contact structures 320. The chip guard structure 330 may include substantially the same material as the contact structures 320 and may include titanium nitride, tungsten, molybdenum, or the like. However, the present disclosure is not limited thereto, and the chip guard structure 330 and the contact structures 320 may be formed at different times. Here, the chip guard structure 330 may include an insulating material such as oxide. The chip guard structure 330 may be preventing or reducing a crack from occurring in the chip region CHR in the process of separating the semiconductor chips in a subsequent process.

When forming the contact structures 320 and the chip guard structure 330, a first contact via 370 may be formed. After removing the sacrificial contact via 370A, the first contact via 370 may be formed. For example, a conductive layer may be formed in the first openings OP1, the fourth opening OP4, and opening (not shown) formed after removing the sacrificial contact via 370A. Each of the contact structures 320, the chip guard structure 330, and the first contact via 370 may be formed by planarizing the conductive layer. Before forming the first contact via 370, an insulating spacer 370S may be formed in the opening formed after removing the sacrificial contact via 370A. For reference, although not shown in the present drawing, because a plurality of sacrificial contact vias 370A of different heights connected to the respective third material layers 310C may be formed in the gate structure 310G, the first contact vias 370 may have different heights and may be connected to the respective third material layers 310C.

Subsequently, the interlayer insulating layer IL may be formed on the first mask pattern M1. Subsequently, the second contact vias CV may be formed. For example, the second contact vias CV extending through the interlayer insulating layer IL and connected to the channel structures 350, the first contact via 370, and the contact structures 320 may be formed. Subsequently, although not shown in the present drawing, a dicing process for separating the semiconductor chips may be performed. Here, because the chip guard structure 330 of the guard region GR is formed to surround the chip region CHR, damage to the chip region CHR from a crack that may occur when dicing may be prevented or reduced.

According to the manufacturing method as described above, when forming the first openings OP1, the second openings OP2 and the third openings OP3 may be formed. In addition, when forming the fourth opening OP4 by connecting the second openings OP2 and the third openings OP3, the first openings OP1 may be extended. Accordingly, a manufacturing process may be simplified by unifying a process of forming and extending the openings OP1, OP2, and OP3.

In addition, the second openings OP2 and the third openings OP3 may have different shapes, arrangements, or sizes. Accordingly, the fourth opening OP4 may include protrusions having different widths, and may protect the chip region CHR from a crack occurring in a subsequent process.

When forming the fourth openings OP4, the first openings OP1 may be extended, the contact structures 320 may be formed in the extended first openings OP1, and thus a resistance of the contact structures 320 connected to the peripheral circuits may be reduced.

Although embodiments according to the technical spirit of the present disclosure have been described with reference to the accompanying drawings, this is only for describing an embodiment according to the concept of the present disclosure, and the present disclosure is not limited to the above-described embodiments. Within the scope of the technical spirit of the present disclosure described in the claims, various forms of substitution, modification, and change of the embodiments will be possible by those skilled in the art to which the present disclosure belongs, and these also belong to the scope of the present disclosure. Furthermore, the embodiments may be combined to form additional embodiments.

What is claimed is:

1. A semiconductor device comprising:
a stack including a chip region and a guard region surrounding the chip region;
contact structures positioned in the chip region; and
a chip guard structure positioned in the guard region and including first protrusions protruding by a first width and second protrusions protruding by a second width greater than the first width.

2. The semiconductor device of claim 1, wherein in a plan view, the chip guard structure has a ring shape.

3. The semiconductor device of claim 1, wherein an upper surface of the contact structures is positioned at the same level as an upper surface of the chip guard structure.

4. The semiconductor device of claim 1, wherein the contact structures and the chip guard structure include the same material.

5. The semiconductor device of claim 4, wherein the contact structures and the chip guard structure include at least one of titanium nitride, tungsten, and molybdenum.

6. The semiconductor device of claim 4, wherein the contact structures and the chip guard structure include an insulating material.

7. The semiconductor device of claim 1, further comprising:
channel structures positioned in the chip region.

8. The semiconductor device of claim 7, further comprising:
supports disposed in the chip region and arranged around the contact structures in a first direction and in a second direction crossing the first direction.

9. The semiconductor device of claim 8, wherein an upper surface of the channel structures is positioned at the same level as an upper surface of the supports.

10. A method of manufacturing a semiconductor device, the method comprising:
forming a stack including a chip region and a guard region surrounding the chip region;
forming first openings extending through the chip region of the stack;
forming second openings and third openings extending through the guard region of the stack and spaced apart from each other;
forming a fourth opening by connecting the second openings and the third openings;
forming contact structures in the first openings; and
forming a chip guard structure in the fourth opening.

11. The method of claim 10, wherein each of the first openings is extended when forming the fourth opening.

12. The method of claim 10, wherein the chip guard structure is formed when forming the contact structures.

13. The method of claim 10, wherein the second openings and the third openings are formed when forming the first openings.

14. The method of claim 10, further comprising:
forming fifth openings extending through the chip region; and
forming channel structures in the fifth openings.

15. The method of claim 14, further comprising:
forming a mask pattern covering the channel structures and exposing the first openings, the second openings, and the third openings,
wherein the first openings, the second openings, and the third openings are selectively extended by using the mask pattern.

16. The method of claim 14, wherein the first openings, the second openings, and the third openings are formed when forming the fifth openings.

17. The method of claim 10, further comprising:
forming sixth openings extending through the chip region; and
forming supports in the sixth openings.

18. The method of claim 17, further comprising:
forming a mask pattern covering the supports and exposing the first openings, the second openings, and the third openings,
wherein the first openings, the second openings, and the third openings are selectively extended by using the mask pattern.

19. The method of claim 17, wherein the first openings, the second openings, and the third openings are formed when forming the sixth openings.

20. The method of claim 10, wherein a width of the third openings is greater than a width of the second openings.

21. The method of claim 10, wherein the second openings have a circular shape, and the third openings have an elliptical shape.

22. The method of claim 10, wherein the second openings are arranged in a first direction, and the third openings are arranged in a second direction crossing the first direction.

23. A semiconductor device comprising:
a stack including a chip region and a guard region surrounding the chip region;
contact structures positioned in the chip region; and
a chip guard structure positioned in the guard region, the chip guard structure having a rectangular ring shape cross-section, with sides comprising consecutive concave shape protrusions.

24. The semiconductor device of claim 23,
wherein the consecutive concave shape protrusions comprise first protrusions of a first width and second protrusions of a second width, and
wherein the second width is greater than the first width.

25. The semiconductor device of claim 24, wherein the second protrusions are disposed individually between a plurality of consecutive first protrusions.
